(19) United States
(12) Patent Application Publication
(10) Pub. No.: US 2006/0127816 A1
(43) Pub. Date: Jun. 15, 2006

(54) Double photolithography methods with reduced intermixing of solvents

(75) Inventors: Yool Kang, Gyeonggi-do (KR); Han-ku Cho, Gyeonggi-do (KR); Sang-Gyun Woo, Gyeonggi-do (KR); Suk-Joo Lee, Gyeonggi-do (KR); Man-Hyung Ryoo, Gyeonggi-do (KR); Mitsuhiro Hata, Gyeonggi-do (KR); Hyung-Rae Lee, Seoul (KR)

Correspondence Address: MYERS BIGEL SIBLEY & SAJOVEC, PO BOX 37428, RALEIGH, NC, 27627, US

(73) Assignee: Samsung Electronics Co., Ltd.

(21) Appl. No.: 11/296,816

(22) Filed: Dec. 7, 2005

(30) Foreign Application Priority Data
Dec. 10, 2004 (KR) 10-2004-0104022

(51) Int. Cl. G03F 7/00

(52) U.S. Cl. 430/312; 430/313

(57) ABSTRACT

The present invention provides a double photolithography method in which, after a first photoresist pattern including a crosslinkable agent is formed on a semiconductor substrate, a crosslinkage is formed in a molecular structure of the first photoresist pattern. A second photoresist film may be formed on a surface of the semiconductor substrate on which the crosslinked first photoresist patterns are formed. Second photoresist patterns may be formed by exposing, post-exposure baking, and developing the second photoresist film.

### CROSS-REFERENCE TO RELATED APPLICATION

This application claims priority under 35 U.S.C. §119 to Korean Patent Application No. 2004-0104022, filed Dec. 10, 2004, the disclosure of which is incorporated herein by reference in its entirety.

### FIELD OF THE INVENTION

The present invention relates to photolithography methods for use in manufacturing a semiconductor device. In particular, the present invention relates to the use of double photolithography methods for forming photoresist patterns and films.

### BACKGROUND OF THE INVENTION

Various methods may be used for manufacturing a semiconductor device. One such method is photolithography, which may be used for forming a specific material pattern on a semiconductor substrate. In the photolithography method, a photoresist film is coated on a semiconductor substrate. The photoresist film may be selectively exposed to light by using an exposure process referred to as a mask. The exposed photoresist film may be baked using a post-exposure bake process and developed whereby photoresist patterns may be formed on the semiconductor substrate.

The photoresist patterns may be finely formed for a high-integration semiconductor device. Various methods may be used to form such fine photoresist patterns, including a double photolithography method. The double photolithography method may provide lower and upper photoresist films coated on a semiconductor substrate. The lower and upper photoresist films, respectively, may then be exposed to light, baked and developed resulting in fine photoresist patterns formed on the semiconductor substrate. However, for successful double lithography, it is desirable that the solvents contained in the lower photoresist patterns and in the upper photoresist film, respectively, are not dissolved or intermixed with each other. To accomplish this, in conventional double photolithography methods, the lower photoresist patterns may be hardened either by irradiating with UV (ultraviolet) light thereon or by implantation using an electron (E)-beam therein prior to coating of the upper photoresist film on the lower photoresist patterns.

When a Chemically Amplified (CA) resist is used for the lower photoresist film in the UV-hardening process, the UV-hardening process may activate an acid generator of the CA resist and deprotect functional groups resulting in reduced carbon density and deterioration of the etching resistance.

The E-beam hardening process may also present issues in its application to the semiconductor manufacturing process, as it may result in shrinkage in the shapes of the lower photoresist patterns.

### SUMMARY OF THE INVENTION

The present invention provides double photolithography methods capable of reducing or preventing the intermixing of solvents as well as reducing or preventing changes in the carbon density and deterioration of the etching resistance.

According to some embodiments of the present invention, there is provided a double photolithography method, wherein first photoresist patterns including a crosslinkable agent may be formed on a semiconductor substrate. A crosslinkage may be formed in a molecular structure of the first photoresist patterns and a second photoresist film may be formed on the surface of the semiconductor substrate on which the crosslinked first photoresist patterns may be formed. Second photoresist patterns may be formed by exposing the second photoresist film to irradiation, subjecting the second photoresist film to a post-exposure baking process, and developing the second photoresist film.

According to some embodiments of the present invention, there is provided a double photolithography method, wherein a first photoresist film including a crosslinkable agent may be formed on a semiconductor substrate, and first photoresist patterns may be formed by exposing the first photoresist film to irradiation, subjecting the first photoresist film to a post-exposure baking process, and developing the first photoresist film. In some embodiments, a crosslinkage may be formed in a molecular structure of the first photoresist patterns and a second photoresist film may be formed on the surface of the semiconductor substrate on which the crosslinked first photoresist patterns may be formed. Second photoresist patterns may be formed by exposing the second photoresist film to irradiation, subjecting the second photoresist film to a post-exposure baking process, and developing the second photoresist film.

As described above, in some embodiments of the double photolithography methods, the first photoresist patterns including the crosslinkable agent may be formed and then baked at temperatures at which the crosslinkable agent can be reacted, whereby a crosslinkage may be formed in a molecular structure of the first photoresist patterns. Accordingly, the double lithography methods of the present invention may be more readily performed than the methods of conventional double lithography.

### BRIEF DESCRIPTION OF THE DRAWINGS

FIGS. 1 through 6 are sectional views illustrating double photolithography methods according to some embodiments of the present invention; and

FIG. 7 is a flowchart illustrating double photolithography methods according to some embodiments of the present invention, which are illustrated in FIGS. 1 through 6.

### DETAILED DESCRIPTION OF EMBODIMENTS ACCORDING TO THE INVENTION

The present invention will now be described more fully herein with reference to the accompanying drawings, in which embodiments of the invention are shown. This invention, however, may be embodied in many different forms and should not be construed as being limited to the embodiments set forth herein. Rather, these embodiments are provided so that this disclosure will be thorough and complete and will fully convey the concept of the invention to those skilled in the art.

The terminology used in the description of the invention herein is for the purpose of describing particular embodiments only and is not intended to be limiting of the invention. As used in the description of the embodiments of the invention and the appended claims, the singular forms “a”, “an” and “the” are intended to include the plural forms as well, unless the context clearly indicates otherwise.

Unless otherwise defined, all terms, including technical and scientific terms used in the description of the invention, have the same meaning as commonly understood by one of ordinary skill in the art to which this invention belongs. All publications, patent applications, patents, and other references mentioned herein are incorporated by reference in their entirety.

It will be further understood that the terms “comprises” and/or “comprising,” when used in this specification, specify the presence of stated features, steps, operations, elements, and/or components, but do not preclude the presence or addition of one or more other features, steps, operations, elements, components, and/or groups thereof.

Moreover, it will be understood that steps comprising the methods provided herein can be performed independently or at least two steps can be combined. Additionally, steps comprising the methods provided herein, when performed independently or combined, can be performed at the same temperature or at different temperatures without departing from the teachings of the present invention.

In the drawings, the thickness of layers and regions are exaggerated for clarity. It will also be understood that when a layer is referred to as being “on” another layer or substrate or a reactant is referred to as being introduced, exposed or feed “onto” another layer or substrate, it can be directly on the other layer or substrate, or intervening layers can also be present. However, when a layer, region or reactant is described as being “directly on” or introduced, exposed or feed “directly onto” another layer or region, no intervening layers or regions are present. Additionally, like numbers refer to like compositions or elements throughout.

Embodiments of the present invention are described herein with reference to cross-section illustrations that are schematic illustrations of idealized embodiments of the present invention. As such, variations from the shapes of the illustrations as a result, for example, of manufacturing techniques and/or tolerances, are to be expected. Thus, embodiments of the present invention should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the precise shape of a region of a device and are not intended to limit the scope of the present invention.

As will be appreciated by one of skill in the art, the present invention may be embodied as compositions and devices including the compositions as well as methods of making and using such compositions and devices.

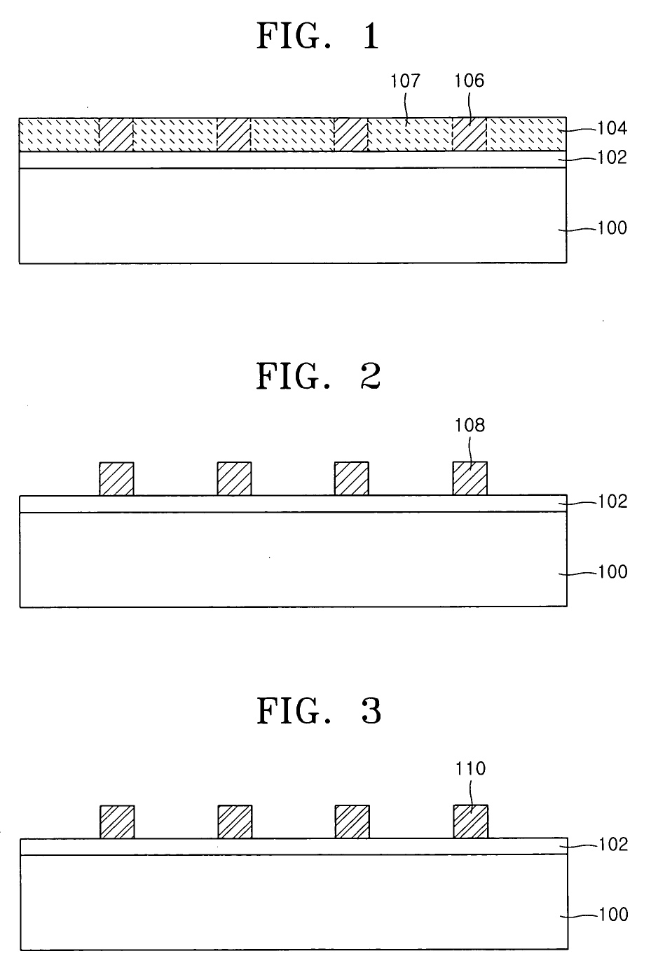

FIGS. 1 through 6 are sectional views illustrating double photolithography methods according to some embodiments of the present invention.

Referring to FIG. 1, an antireflection film 102 may be formed on a semiconductor substrate 100. In some embodiments of the invention, the antireflection film 102 may not be formed. When formed, the antireflection film 102 may comprise an organic antireflection film, an inorganic antireflection film, a water-soluble antireflection film, or the like.

According to some embodiments, a first photoresist film (or a lower photoresist film) 104 containing a crosslinkable agent may be formed on the antireflection film 102 through a coating process. The first photoresist film 104 may comprise a photoresist including, but not limited to, a positive photoresist or a negative photoresist. Further, in some embodiments, the first photoresist film 104 may comprise a photoresist including, but not limited to, a chemically amplified (CA) resist. In some embodiments, the crosslinkable agent of the first photoresist film 104 may comprise tri-phenyl ether.

The first photoresist film 104 may be selectively irradiated, for example, exposed to light, using a first exposure process using a mask through which the light is projected onto the photoresist film layer. Through the first exposure process, exposed areas 107 and non-exposed areas 106 may be formed in the first photoresist film 104.

Referring to FIG. 2, the exposed first photoresist film 104 may be baked using a first post-exposure bake process and developed using a first development process whereby first photoresist patterns (lower photoresist patterns) 108 may be formed. The first post-exposure bake process may be performed in such a way that the crosslinkable agent is not reacted. In some embodiments, the first post-exposure bake process may be performed at a temperature in a range from about 90° C. to about 130° C. According to some embodiments of the present invention, when a positive photoresist is used for the first photoresist film 104, the first photoresist patterns 108 may be formed in the non-exposed areas 106.

Referring to FIG. 3, crosslinked first photoresist patterns 110 may be formed in a molecular structure of the first photoresist patterns 108. The crosslinkage can be formed in the first photoresist patterns 108 by baking the semiconductor substrate 100, on which the first photoresist patterns 108 have been formed, at a temperature in a range from about 150° C. to about 200° C. Thus, the bake process for the crosslinkage may be performed at higher temperatures than those used with the first post-exposure bake process.

According to some embodiments, the first photoresist patterns 108 may be formed on the semiconductor substrate 100 and the crosslinkage may occur in the first photoresist patterns 108 through the bake process, while not significantly affecting the carbon density or causing substantial deterioration in the etching resistance. In some embodiments, the crosslinkage may be a linkage between hydroxyl (OH) groups of a novolac or styrene polymer in the first photoresist patterns 108. Accordingly, in some embodiments of the present invention, since the first photoresist patterns 110 may be crosslinked, the solvent for use with the crosslinked first photoresist patterns 110 may be reduced or prevented from intermixing with a solvent of a second photoresist film 112 to be formed on the first photoresist patterns 110 in a subsequent process.

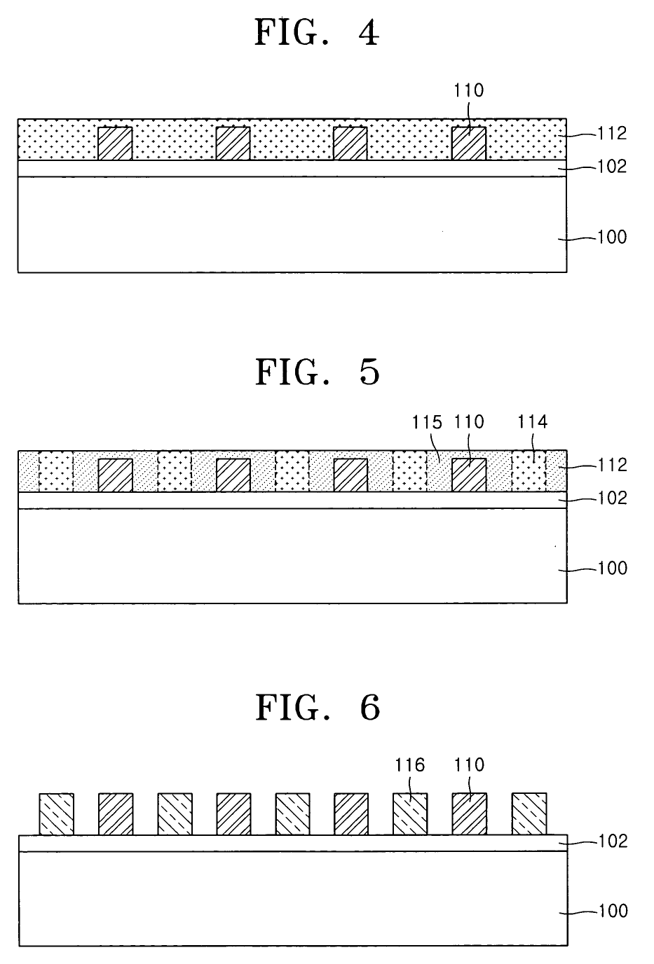

Referring to FIG. 4, a second photoresist film (or an upper photoresist film) 112 may be coated and formed on an entire surface of the semiconductor substrate 100 on which the crosslinked first photoresist patterns 110 have been formed. Thus, in some embodiments, the second photoresist film completely covers the crosslinked first photoresist patterns 110.

In some embodiments of the present invention, the second photoresist film 112 may be formed from a photoresist including, but not limited to, a positive photoresist or a negative photoresist. Further, the second photoresist film 112 may be formed from a photoresist including, but not limited to, a CA resist.

Referring to FIG. 5, the second photoresist film 112 may be selectively exposed to light by using a second exposure process using a second mask. Through the second exposure process, exposed areas 115 and non-exposed areas 114 may be formed in the second photoresist film 112.

Referring to FIG. 6, the exposed second photoresist film 112 may be baked using a second post-exposure bake process and developed using a second development process whereby second photoresist patterns (upper photoresist patterns) 116 may be formed. In some embodiments, when a positive photoresist is used for the second photoresist film 112, the second photoresist patterns 116 are formed in the non-exposed areas 114. In some embodiments, the second photoresist patterns 116 may be formed between the crosslinked first photoresist patterns 110. In some embodiments, the second photoresist patterns 116 may be formed on the crosslinked first photoresist patterns 110.

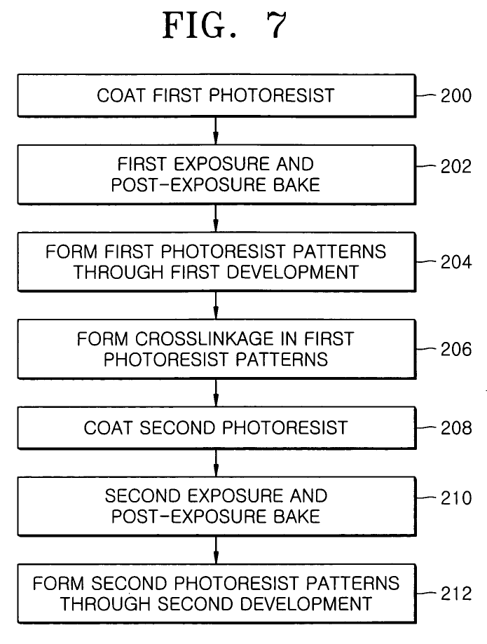

FIG. 7 is a flowchart illustrating double photolithography methods according to the present invention and as shown in FIGS. 1 through 6.

Referring to FIG. 7, in procedure 200, a first photoresist containing a crosslinkable agent may be coated on a semiconductor substrate whereby a first photoresist film may be formed on the semiconductor substrate. In procedure 202, the first photoresist film may be selectively irradiated, for example, exposed to light, by using a first exposure process referred to as a mask, and then baked using a first post-exposure bake process. The first post-exposure bake process may be performed at a temperature in a range from about 90° C. to about 130° C. at which the crosslinkable agent is not reacted.

In procedure 204, the baked first photoresist film may be developed using a first development process whereby first photoresist patterns may be formed on the semiconductor substrate. In procedure 206, a crosslinkage may be formed in the first photoresist patterns by baking the semiconductor substrate, on which the first photoresist patterns have been formed, at temperatures higher than those used in the first post-exposure bake process. Accordingly, in some embodiments, the semiconductor substrate is baked at temperatures in a range from about 150° C. to about 200° C.

In procedure 208, a second photoresist may be coated on an entire surface of the semiconductor substrate on which the crosslinked first photoresist patterns have been formed, whereby a second photoresist film is formed. Due, at least in part, to the crosslinkage, the solvent of the first photoresist patterns may be reduced or prevented from intermixing with a solvent of the second photoresist film.

In procedure 210, the second photoresist film is selectively irradiated, for example, exposed to light, using a second exposure process referred-to as a mask, and baked using a second post-exposure bake process. In procedure 212, the baked second photoresist film is developed using a second development process whereby second photoresist patterns are formed on the semiconductor substrate.

As stated above, in the double photolithography methods of the present invention, the first photoresist patterns containing the crosslinkable agent may be formed and baked at temperatures at which the crosslinkable agent can be reacted, whereby a crosslinkage is formed in a molecular structure of the first photoresist patterns. Accordingly, the carbon density of the first photoresist patterns may not be significantly changed and the etching resistance of the first photoresist patterns may not be significantly deteriorated. Also, since the second photoresist film may be formed on the crosslinked first photoresist patterns, intermixing of the solvent of the first photoresist pattern with a solvent of the second photoresist film may be reduced or prevented, allowing the double lithography methods of the present invention to be performed more readily than conventional double photolithography methods.

While the present invention has been particularly shown and described with reference to some embodiments thereof, it will be understood by those of ordinary skill in the art that various changes in form and details may be made therein without departing from the spirit and scope of the present invention as defined by the following claims.

What is claimed is:

1. A photolithography method comprising:
forming a first photoresist pattern comprising a crosslinkable agent on a semiconductor substrate;
forming a crosslinkage in a molecular structure of the first photoresist pattern;
forming an upper photoresist film on the surface of the semiconductor substrate whereupon the crosslinked first photoresist pattern is formed; and
forming a second photoresist pattern by:
exposing the upper photoresist film to irradiation;
subjecting the upper photoresist film to a post-exposure baking process; and
developing the upper photoresist film.

2. The method of claim 1, wherein forming the first photoresist pattern comprises:
forming a lower photoresist film comprising the crosslinkable agent on the semiconductor substrate; and
exposing the lower photoresist film to irradiation,
subjecting the lower photoresist film to a post-exposure baking process, and
developing the lower photoresist film.

3. The method of claim 1, wherein the upper photoresist film is formed on an entire surface of the semiconductor.

4. The method of claim 2, wherein the post-exposure baking process for the lower photoresist pattern reduces or prevents the reactivity of the crosslinkable agent.

5. The method of claim 2, wherein the post-exposure baking process for the lower photoresist pattern is performed at a temperature in a range from about 90° C. to about 130° C.

6. The method of claim 2, wherein the lower photoresist film comprises a positive photoresist or a negative photoresist.

7. The method of claim 1, wherein the crosslinkage in the molecular structure is formed by subjecting the semiconductor substrate to a baking process.

8. The method of claim 7, wherein the baking process occurs at a temperature that is higher than the temperature employed for the post-exposure baking process.

9. The method of claim 7, wherein the baking process for the crosslinkage occurs at a temperature in a range from about 150° C. to about 200° C.

10. The method of claim 1, wherein the crosslinkable agent comprises tri-phenyl ether.

11. A photolithography method comprising:
forming a first photoresist film comprising a crosslinkable agent on a semiconductor substrate;
forming a first photoresist pattern by:
exposing the first photoresist film to irradiation;
subjecting the first photoresist film to a post-exposure baking process; and
developing the first photoresist film;
forming a crosslinkage in a molecular structure of the first photoresist pattern;
forming a second photoresist film on the surface of the semiconductor substrate whereupon the crosslinked first photoresist pattern is formed; and
forming a second photoresist pattern by:
exposing the second photoresist film to irradiation;
subjecting the second photoresist film to a post-exposure baking process; and
developing the second photoresist film.

12. The method of claim 11, wherein the second photoresist film is formed on an entire surface of the semiconductor.

13. The method of claim 11, wherein the post-exposure baking process for the first photoresist pattern reduces or prevents the reactivity of the crosslinkable agent.

14. The method of claim 11, wherein the post-exposure baking process for the first photoresist pattern is performed at a temperature in a range from about 90° C. to about 130° C.

15. The method of claim 11, wherein the first photoresist film comprises a positive photoresist or a negative photoresist.

16. The method of claim 11, wherein the crosslinkage in the molecular structure is formed by subjecting the semiconductor substrate to a baking process.

17. The method of claim 16, wherein the baking process occurs at a temperature that is higher than the temperature employed for the post-exposure baking process.

18. The method of claim 16, wherein the baking process is performed at a temperature in a range from about 150° C. to about 200° C.

19. The method of claim 11, wherein the crosslinkable agent comprises tri-phenyl ether.

20. A method for forming a crosslinked photoresist pattern comprising:
forming a first photoresist pattern by heating a first photoresist film at a first temperature; and then
heating the first photoresist pattern at a second temperature that is greater than the first temperature.

21. The method of claim 20, wherein the first temperature is in a range from about 90° C. to about 130° C.

22. The method of claim 20, where in the second temperature is in a range from about 150° C. to about 200° C.
